(19) United States
(12) Patent Application Publication
(10) Pub. No.: US 2011/0139073 A1
(43) Pub. Date: Jun. 16, 2011

(54) CONVEYOR ASSEMBLY FOR A VAPOR DEPOSITION APPARATUS

(75) Inventors: MAX WILLIAM REED, NIWOT, CO (US); RUSSELL WELDON BLACK, LONGMONT, CO (US)

(73) Assignee: PRIMESTAR SOLAR, INC., ARVADA, CO (US)

(21) Appl. No.: 12/638,772

(22) Filed: Dec. 15, 2009

(51) Int. Cl. H01L 31/18; B65G 17/06; B65G 17/30

(52) U.S. Cl. 118/729; 198/845; 198/850; 257/E31.001

(57) ABSTRACT

A conveyor assembly for use in a vapor deposition apparatus includes a housing defining an enclosed interior volume. A conveyor is driven in an endless loop path within the housing. The housing has a top member that defines an open deposition area in an upper conveyance leg of the conveyor. The conveyor includes a plurality of interconnected slats, with each slat having a respective flat, planar outer surface and transverse edge profiles such that, in the upper conveyance leg of the conveyor, the outer surfaces of the slats lie in a common horizontal plane and define an uninterrupted flat support surface for a substrate conveyed through the vapor deposition apparatus.

### FIELD OF THE INVENTION

The subject matter disclosed herein relates generally to the field of thin film deposition systems wherein a thin film layer, such as a semiconductor material layer, is deposited on a substrate conveyed through the system. More particularly, the subject matter is related to a conveyor unit for use in a vapor deposition apparatus that is particularly suited for depositing a thin film layer of a photo-reactive material on a glass substrate in the formation of photovoltaic (PV) modules.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy (sunlight) to electricity. For example, CdTe has an energy bandgap of 1.45 eV, which enables it to convert more energy from the solar spectrum as compared to lower bandgap (1.1 eV) semiconductor materials historically used in solar cell applications. Also, CdTe converts energy in lower or diffuse light conditions as compared to the lower bandgap materials and, thus, has a longer effective conversion time over the course of a day or in low-light (e.g., cloudy) conditions as compared to other conventional materials.

Solar energy systems using CdTe PV modules are generally recognized as the most cost efficient of the commercially available systems in terms of cost per watt of power generated. However, the advantages of CdTe not withstanding, sustainable commercial exploitation and acceptance of solar power as a supplemental or primary source of industrial or residential power depends on the ability to produce efficient PV modules on a large scale and in a cost effective manlier.

Certain factors greatly affect the efficiency of CdTe PV modules in terms of cost and power generation capacity. For example, CdTe is relatively expensive and, thus, efficient utilization (i.e., minimal waste) of the material is a primary cost factor. In addition, the energy conversion efficiency of the module is a factor of certain characteristics of the deposited CdTe film layer. Non-uniformity or defects in the film layer can significantly decrease the output of the module, thereby adding to the cost per unit of power. In addition, the ability to process relatively large substrates on an economically sensible commercial scale is a crucial consideration.

CSS (Close Space Sublimation) is a known commercial vapor deposition process for production of CdTe modules. Reference is made, for example, to U.S. Pat. No. 6,444,043 and U.S. Pat. No. 6,423,565. Within the vapor deposition chamber in a CSS process, the substrate is brought to an opposed position at a relatively small distance (i.e., about 2-3 mm) opposite to a CdTe source. The CdTe material sublimes and deposits onto the surface of the substrate. In the CSS system of U.S. Pat. No. 6,444,043 cited above, the CdTe material is in granular form and is held in a heated receptacle within the vapor deposition chamber. The sublimated material moves through holes in a cover placed over the receptacle and deposits onto the stationary glass surface, which is held at the smallest possible distance (1-2 mm) above the cover frame. The cover is heated to a temperature greater than the receptacle.

While there are advantages to known CSS processes, the systems are inherently a batch process wherein the glass substrate is indexed into a vapor deposition chamber, held in the chamber for a finite period of time in which the film layer is formed, and subsequently indexed out of the chamber. The system is more suited for batch processing of relatively small surface area substrates. The process must be periodically interrupted in order to replenish the CdTe source, which is detrimental to a large scale production process. In addition, the deposition process cannot readily be stopped and restarted in a controlled manner, resulting in significant non-utilization (i.e., waste) of the CdTe material during the indexing of the substrates into and out of the chamber, and during any steps needed to position the substrate within the chamber.

Accordingly, there exists an ongoing need in the industry for an improved vapor depositon apparatus for economically feasible large scale production of efficient PV modules, particularly CdTe modules. The present invention relates to a conveyor unit that serves this purpose.

### BRIEF DESCRIPTION OF THE INVENTION

Aspects and advantages of the invention will be set forth in part in the following description, or may be obvious from the description, or may be learned through practice of the invention.

In accordance with an embodiment of the invention, a conveyor assembly is provided that is particularly suited for use in a vapor deposition apparatus wherein a sublimated source material, such as CdTe, is deposited as a thin film layer on a photovoltaic (PV) module substrate. The conveyor assembly includes a housing that defines an enclosed interior volume. A conveyor is operably disposed within the housing and is driven in an endless loop path within the housing, for example between opposite sprockets, with at least one of the sprockets being a drive sprocket. The endless loop path of the conveyor includes an upper leg that moves in a conveyance direction of the substrates through the assembly, and a lower leg that moves in an opposite return direction. The housing includes a top member that defines an open vapor deposition area wherein the conveyor (and thus a substrate carried on the conveyor) is exposed to sublimated source material as the conveyor moves along the upper leg of the endless loop path. In a particular embodiment, the conveyor is formed from a plurality of interconnected slats, with each slat having a respective flat, planar, outer surface and transverse edge profiles such that, along at least the upper leg of the endless loop path, the outer surfaces of the slats lie in a common horizontal plane and define an uninterrupted flat support surface for a substrate conveyed through the assembly.

Variations and modifications to the embodiment of the conveyor assembly discussed above are within the scope and spirit of the invention and may be further described herein.

The present invention also encompasses a vapor deposition module that incorporates a conveyor assembly in accordance with aspects of the invention. For example, the invention provides a vapor deposition module for deposition of a sublimated source material, such as CdTe, as a thin film on a photovoltaic (PV) module substrate that is conveyed through the vapor deposition module. The module includes a casing, and a vapor deposition head operably configured within the casing to sublimate a source material. A conveyor assembly is operably configured within the casing below the vapor deposition head, and includes a housing that defines an enclosed interior volume. A conveyor is operably disposed within the housing and is drivable in an endless loop path within the housing. The endless loop path has an upper leg that moves in a conveyance direction of a substrate through the module, and a lower leg that moves in an opposite return direction. The housing further includes a top member that defines an open deposition area wherein the conveyor (and thus the upper surface of a substrate supported on the conveyor) is exposed to the vapor deposition head as the conveyor moves along the upper leg of the endless loop path.

The conveyor may include a plurality of interconnected slats, with each slat having a respective flat, planar, outer surface and transverse edge profiles such that, along the upper leg of the endless loop path, the outer surfaces of the slats lie in a common horizontal plane and define an uninterrupted flat support surface for a substrate conveyed through the module. The vapor deposition head is configured on the conveyor assembly housing such that sublimated source material from the vapor deposition head is directed to the open deposition area and onto the upper surface of a substrate supported by the conveyor.

Variations and modifications to the embodiment of the vapor deposition module discussed above are within the scope and spirit of the invention and may be further described herein.

These and other features, aspects and advantages of the present invention will become better understood with reference to the following description and appended claims.

### BRIEF DESCRIPTION OF THE DRAWING

A full and enabling disclosure of the present invention, including the best mode thereof, is set forth in the specification, which makes reference to the appended drawings, in which:

FIG. 1 is a plan view of a vapor deposition system that may incorporate embodiments of the conveyor assembly of the present invention;

FIG. 2 is a cross-sectional view of a particular embodiment of a conveyor assembly in accordance with aspects of the invention;

FIG. 3 is a partial perspective view of components of the conveyor assembly depicted in FIG. 2;

FIG. 4 is an additional partial perspective view of components of the assembly depicted in FIG. 2;

FIG. 5 is a partial perspective view of an embodiment of the conveyor slats in accordance with aspects of the invention; and,

FIG. 6 is a side view of the conveyor of FIG. 5.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention encompass such modifications and variations as come within the scope of the appended claims and their equivalents.

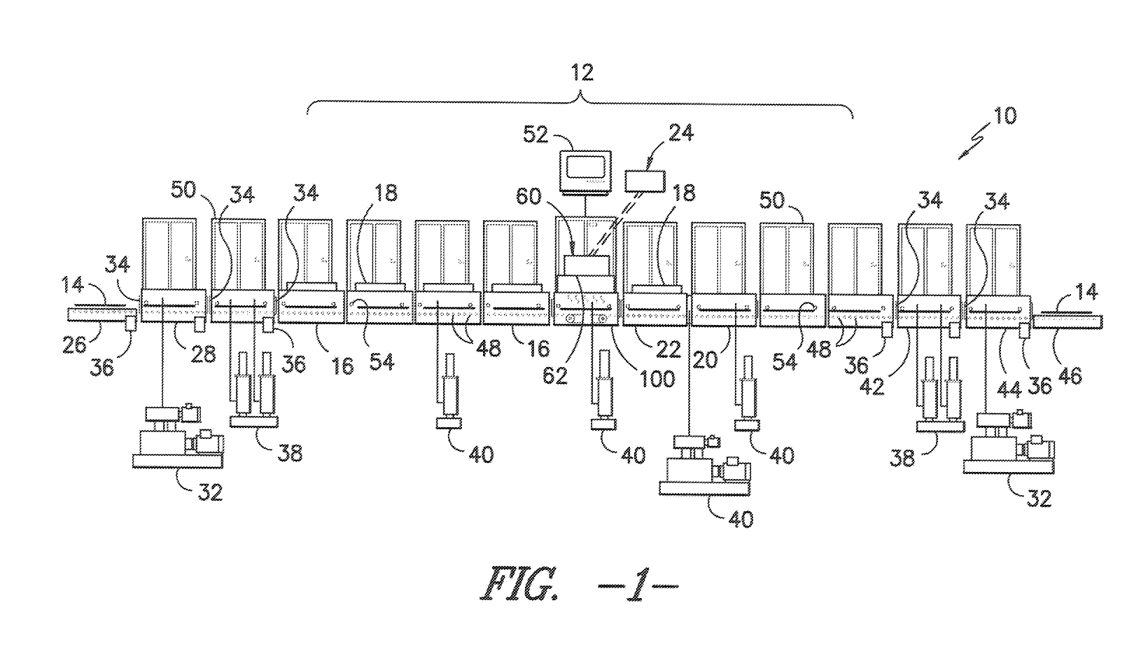

FIG. 1 illustrates an embodiment of a vapor deposition system 10 that may incorporate a conveyor assembly in accordance with aspects of the invention, particularly as a component of a vapor deposition module or component. The system 10 is configured for deposition of a thin film layer on a photovoltaic (PV) module substrate 14 (referred to hereafter as “substrate”). The thin film may be, for example, a film layer of cadmium telluride (CdTe). Although the invention is not limited to any particular film thickness, as mentioned, it is generally recognized in the art that a “thin” film layer on a PV module substrate is generally less than about 10 microns (μm). It should be appreciated that the present cool-down system and process is not limited to use in the system 10 illustrated in FIG. 1, but may be incorporated into any suitable processing line configured for vapor deposition of a thin film layer onto a PV module substrate 14.

For reference and an understanding of an environment in which the present conveyor assembly may be used, the system 10 of FIG. 1 is described below, followed by a detailed description of the conveyor assembly.

Referring to FIG. 1, the exemplary system 10 includes a vacuum chamber 12 defined by a plurality of interconnected modules. Any combination of rough and fine vacuum pumps 40 may be configured with the modules to draw and maintain a vacuum within the chamber 12. A plurality of interconnected heater modules 16 define a pre-heat section of the vacuum chamber 12 through which the substrates 14 are conveyed and heated to a desired temperature before being conveyed into the vapor deposition apparatus 60. Each of the modules 16 may include a plurality of independently controlled heaters 18, with the heaters defining a plurality of different heat zones. A particular heat zone may include more than one heater 18.

The vacuum chamber 12 also includes a plurality of interconnected cool-down modules 20 within the vacuum chamber 12 downstream of the vapor deposition apparatus 60. The cool-down modules 20 define a cool-down section within the vacuum chamber 12 in which the substrates 14 having the thin film of sublimed source material deposited thereon are allowed to cool at a controlled cool-down rate prior to the substrates 14 being removed from the system 10. Each of the modules 20 may include a forced cooling system wherein a cooling medium, such as chilled water, refrigerant, or other medium is pumped through cooling coils configured with the modules 20.

In the illustrated embodiment of system 10, at least one post-heat module 22 is located immediately downstream of the vapor deposition apparatus 60 and before the cool-down modules 20. The post-heat module 22 maintains a controlled heating profile of the substrate 14 until the entire substrate is moved out of the vapor deposition apparatus 60 to prevent damage to the substrate, such as warping or breaking caused by uncontrolled or drastic thermal stresses. If the leading section of the substrate 14 were allowed to cool at an excessive rate as it exited the apparatus 60, a potentially damaging temperature gradient would be generated longitudinally along the substrate 14. This condition could result in breaking, cracking, or warping of the substrate from thermal stress.

As diagrammatically illustrated in FIG. 1, a feed device 24 is configured with the vapor deposition apparatus 60 to supply source material, such as granular CdTe. Preferably, the feed device 24 is configured so as to supply the source material without interrupting the continuous vapor deposition process within the apparatus 60 or conveyance of the substrates 14 through the apparatus 60.

Still referring to FIG. 1, the individual substrates 14 are initially placed onto a load conveyor 26, and are subsequently moved into an entry vacuum lock station that includes a load module 28 and a buffer module 30. A “rough” (i.e., initial) vacuum pump 32 is configured with the load module 28 to drawn an initial vacuum, and a “fine” (i.e., high) vacuum pump 38 is configured with the buffer module 30 to increase the vacuum in the buffer module 30 to essentially the vacuum within the vacuum chamber 12. Valves 34 (e.g., gate-type slit valves or rotary-type flapper valves) are operably disposed between the load conveyor 26 and the load module 28, between the load module 28 and the buffer module 30, and between the buffer module 30 and the vacuum chamber 12. These valves 34 are sequentially actuated by a motor or other type of actuating mechanism 36 in order to introduce the substrates 14 into the vacuum chamber 12 in a step-wise manner without affecting the vacuum within the chamber 12.

An exit vacuum lock station is configured downstream of the last cool-down module 20, and operates essentially in reverse of the entry vacuum lock station described above. For example, the exit vacuum lock station may include an exit buffer module 42 and a downstream exit lock module 44. Sequentially operated slide valves 34 are disposed between the buffer module 42 and the last one of the cool-down modules 20, between the buffer module 42 and the exit lock module 44, and between the exit lock module 44 and an exit conveyor 46. A fine vacuum pump 38 is configured with the exit buffer module 42, and a rough vacuum pump 32 is configured with the exit lock module 44. The pumps 32, 38 and valves 34 are sequentially operated to move the substrates 14 out of the vacuum chamber 12 in a step-wise fashion without loss of vacuum condition within the vacuum chamber 12.

System 10 also includes a conveyor system configured to move the substrates 14 into, through, and out of the vacuum chamber 12. In the illustrated embodiment, this conveyor system includes a plurality of individually controlled conveyors 48, with each of the various modules including one of the conveyors 48. It should be appreciated that the type or configuration of the conveyors 48 in the various modules may vary. In the illustrated embodiment, the conveyors 48 are roller conveyors having driven rollers that are controlled so as to achieve a desired conveyance rate of the substrates 14 through the respective module and the system 10 overall.

As described, each of the various modules and respective conveyors in the system 10 are independently controlled to perform a particular function. For such control, each of the individual modules may have an associated independent controller 50 configured therewith to control the individual functions of the respective module. The plurality of controllers 50 may, in turn, be in communication with a central system controller 52, as illustrated in FIG. 1. The central system controller 52 can monitor and control (via the independent controllers 50) the functions of any one of the modules so as to achieve an overall desired heat-up rate, deposition rate, cool-down rate, and so forth, in processing of the substrates 14 through the system 10.

Referring to FIG. 1, for independent control of the individual respective conveyors 48, each of the modules may include any mariner of active or passive sensor 54 that detects the presence of the substrates 14 as they are conveyed through the module. The sensors 54 are in communication with the respective module controller 50, which is in turn in communication with the central controller 52. In this manner, the individual respective conveyor 48 may be controlled to ensure that a proper spacing between the substrates 14 is maintained and that the substrates 14 are conveyed at the desired constant conveyance rate through the vacuum chamber 12.

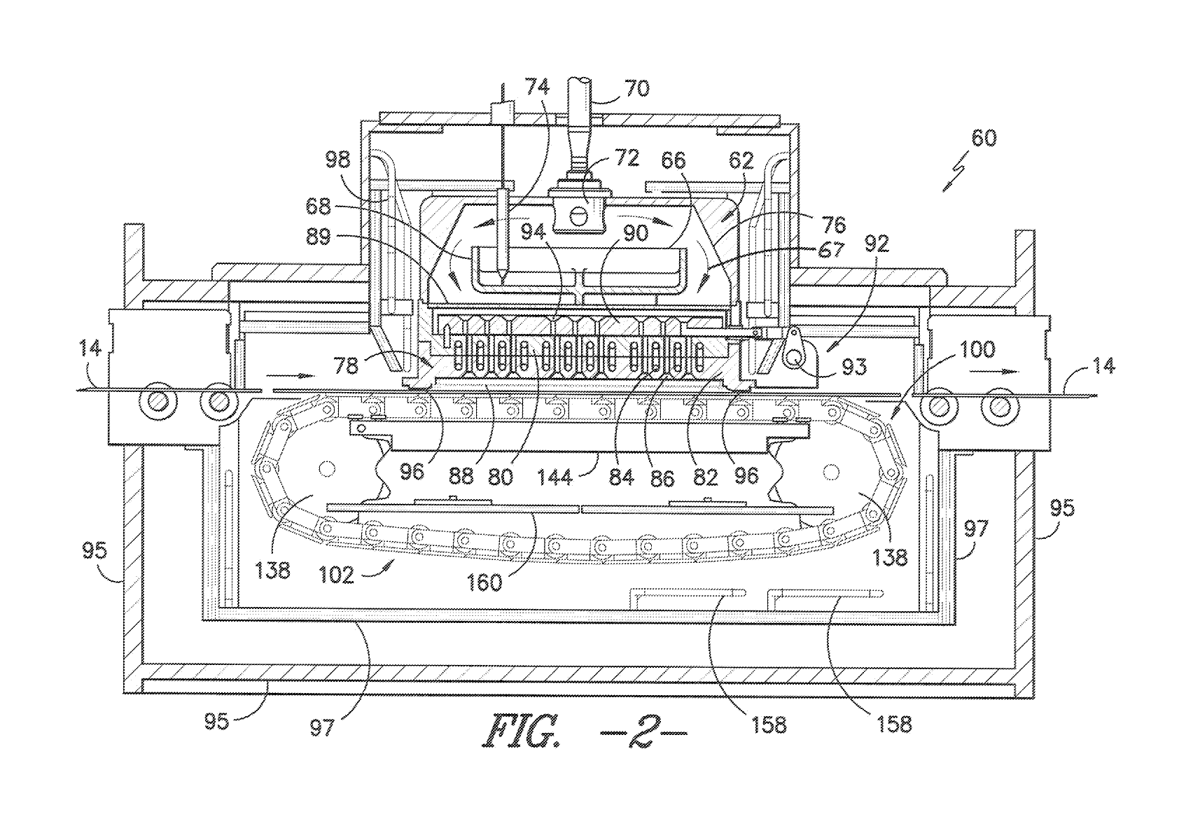

The vapor deposition apparatus 60 may take on various configurations and operating principles within the scope and spirit of the invention, and is generally configured for vapor deposition of a sublimated source material, such as CdTe, as a thin film on the PV module substrates 14. In the embodiment of the system 10 illustrated in FIG. 1, the apparatus 60 is a module that includes a casing 95 (FIG. 2) in which the internal components are contained, including a vacuum deposition head 62 mounted above a conveyor assembly 100. It should be appreciated that the casing 95 may include any mariner of internal structure 97 that may support the conveyor assembly 100.

Referring to FIG. 2, the module 60 is depicted in greater detail. The vacuum deposition head 62 defines an interior space in which a receptacle 66 is configured for receipt of a granular source material (not shown). As mentioned, the granular source material may be supplied by a feed device or system 24 (FIG. 1) via a feed tube 70. The feed tube 70 is connected to a distributor 72 disposed in an opening in a top wall of the vapor deposition head 62. The distributor 72 includes a plurality of discharge ports that are configured to evenly distribute the granular source material into the receptacle 66.

In the illustrated embodiment, at least one thermocouple 74 is operationally disposed through the top wall of the deposition head 62 to monitor temperature within the head chamber adjacent or in the receptacle 66.

The receptacle 66 has a shape and configuration such that end walls 68 of the receptacle 66 are spaced from end walls 76 of the deposition head 62. The side walls of the receptacle 66 lie adjacent to and in close proximity to the side walls of the deposition head 62 (not visible in the view of FIG. 2) so that very little clearance exists between the respective side walls. With this configuration, sublimated source material will flow out of the receptacle 66 as leading and trailing curtains of vapor 67 over the transversely extending end walls 68, as indicated by the flow arrows in FIG. 2. Very little of the sublimated source material will flow over the side walls of the receptacle 66.

A heated distribution manifold 78 is disposed below the receptacle 66, and may have a clam-shell configuration that includes an upper shell member 80 and a lower shell member 82. The mated shell members 80, 82 define cavities in which heater elements 84 are disposed. The heater elements 84 heat the distribution manifold 78 to a degree sufficient for indirectly heating the source material within the receptacle 66 to cause sublimation of the source material. The heat generated by the distribution manifold 78 also aids in preventing the sublimated source material from plating out onto components of the deposition head 62. Additional heater elements 98 may also be disposed within the deposition head 62 for this purpose. Desirably, the coolest component within the deposition head 62 is the upper surface of the substrates 14 conveyed therethrough so that the sublimated source material is ensured to plate primarily on the substrates.

Still referring to FIG. 2, the heated distribution manifold 78 includes a plurality of passages 86 defined therethrough. These passages have a shape and configuration so as to uniformly distribute the sublimated source material towards the underlying substrates 14.

A distribution plate 88 is disposed below the manifold 78 at a defined distance above a horizontal plane of the upper surface of an underlying substrate 14, as depicted in FIG. 2. The distribution plate 88 includes a pattern of holes or passages therethrough that further distribute the sublimated source material passing through the distribution manifold 78.

As previously mentioned, a significant portion of the sublimated source material will flow out of the receptacle 66 as transversely extending leading and trailing curtains of vapor. Although these curtains of vapor will diffuse to some extent in the longitudinal direction (direction of conveyance of the substrates) prior to passing through the distribution plate 88, it should be appreciated that it is unlikely that a uniform distribution of the sublimated source material in the longitudinal direction will be achieved. In other words, more of the sublimated source material will be distributed through the longitudinal end sections of the distribution plate 88 as compared to the middle portion of the distribution plate. However, as discussed above, because the system 10 conveys the substrates 14 through the vapor deposition apparatus 100 at a non-stop constant linear speed, the upper surfaces of the substrates 14 will be exposed to the same deposition environment regardless of any non-uniformity of the vapor distribution along the longitudinal aspect of the apparatus 60. The passages 86 in the distribution manifold 78 and the holes in the distribution plate 88 ensure a relatively uniform distribution of the sublimated source material in the transverse aspect of the vapor deposition apparatus 60. So long as the uniform transverse aspect of the vapor is maintained, a relatively uniform thin film layer is deposited onto the upper surface of the substrates 14.

As illustrated in FIG. 2, it may be desired to include a debris shield 89 between the receptacle 66 and the distribution manifold 78. This shield 89 may include relatively large holes defined therethrough (as compared to the distribution plate 88) and serves to retain any granular or particulate source material from passing through and potentially interfering with operation of the other components of the deposition head 62. In another embodiment, the holes may be very small, or the shield may be a mesh screen, so as to prevent even very small granules or particles of solid source material from passing through the shield.

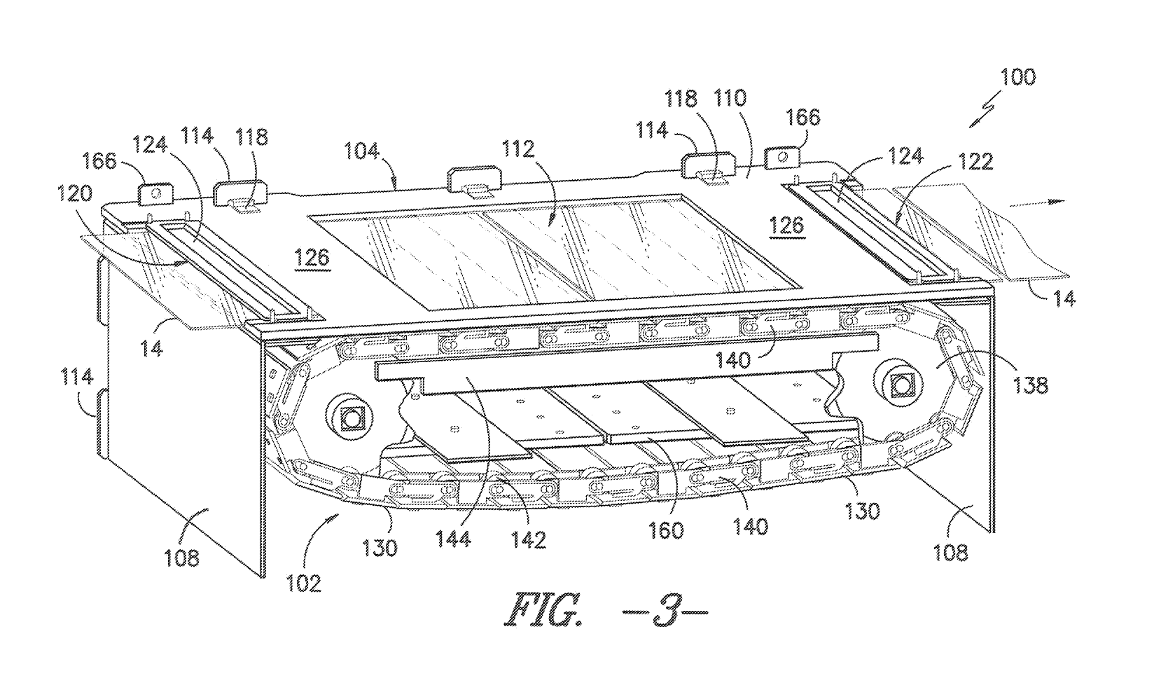

Still referring to FIG. 2, the deposition head 62 may include transversely extending seals 96 at each longitudinal end thereof. In the illustrated embodiment, the seals 96 are defined by components of the lower shell member 82 of the heated distribution manifold 78. In one embodiment, these seals 96 may be disposed at a distance above the upper surface of the substrates 14 that is less than the distance between the surface of the substrates 14 and the distribution plate 88. The seals 96 help to maintain the sublimated source material in the deposition area above the substrates. In other words, the seals 96 prevent the sublimated source material from “leaking” out through the longitudinal ends of the apparatus 60. It should be appreciated that, in alternative embodiments, the seals 96 may be engaged against opposite structure in the apparatus 60 and serve the same function, as discussed in greater detail below with respect to the embodiment of FIG. 3.

The embodiment of FIG. 2 includes a movable shutter plate 90 disposed above the distribution manifold 78. This shutter plate 90 includes a plurality of passages 94 defined therethrough that align with the passages 86 in the distribution manifold 78 in a first operational position of the shutter plate 90 such that the sublimated source material is free to flow through the shutter plate 90 and through the distribution manifold 78 for subsequent distribution through the plate 88. The shutter plate 90 is movable to a second operational position wherein the passages 94 are misaligned with the passages 86 in the distribution manifold 78. In this configuration, the sublimated source material is blocked from passing through the distribution manifold 78, and is essentially contained within the interior volume of the deposition head 62.

Any suitable actuation mechanism 92 may be configured for moving the shutter plate 90 between the first and second operational positions. In the illustrated embodiment, the actuation mechanism 92 includes a rod 93 and any manner of suitable linkage that connects the rod 93 to the shutter plate 90. The rod 93 is externally rotated by any manner of mechanism located externally of the deposition head 62. The shutter plate 90 is particularly beneficial in that, for whatever reason, the sublimated source material can be quickly and easily contained within the deposition head 62 and prevented from passing through to the deposition area above the substrates 14 or conveyor assembly 100. This may be desired, for example, during start up of the system 10 while the concentration of vapors within the deposition head chamber builds to a sufficient degree to start the deposition process. Likewise, during shutdown of the system, it may be desired to maintain the sublimated source material within the deposition head 62 chamber to prevent the material from plating out on the conveyor or other components of the apparatus 60.

Referring to FIGS. 2 through 4, various embodiments of a conveyor assembly 100 are illustrated. In FIG. 2, the conveyor assembly 100 is contained within the module casing 95 and is disposed below the vapor deposition head 62. As described in greater detail below, the conveyor assembly 100 may, in a desirable embodiment, be modular in construction and include a housing 104, as depicted in FIG. 3. The housing 104 has been removed in the view of FIG. 2 for sake of clarity and explanation.

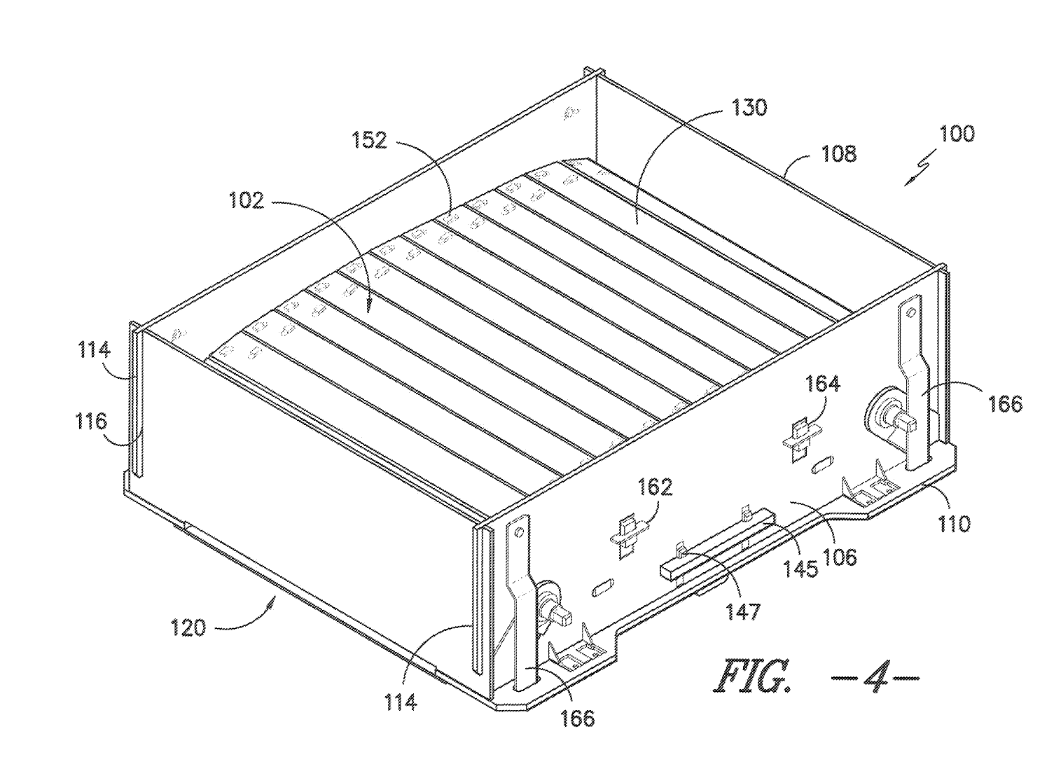

Referring to FIGS. 3 and 4 in particular, the housing 104 defines an enclosed interior volume (at least around the sides and top) in which the conveyor 102 is contained. The conveyor 102 is driven in an endless loop within the housing 104, with this endless loop having an upper leg that moves in a conveyance direction of the substrates 14 through the vapor deposition head 62, and a lower leg that moves in an opposite return direction. The housing 104 includes a top member 110 that defines an open deposition area 112. Referring to FIG. 2, this open deposition area 112 aligns with the vapor deposition head 62, particularly the distribution plate 88. As can be seen in FIG. 3, the upper surface of the substrates 14 are exposed to the distribution plate 88 in the open deposition area 112.

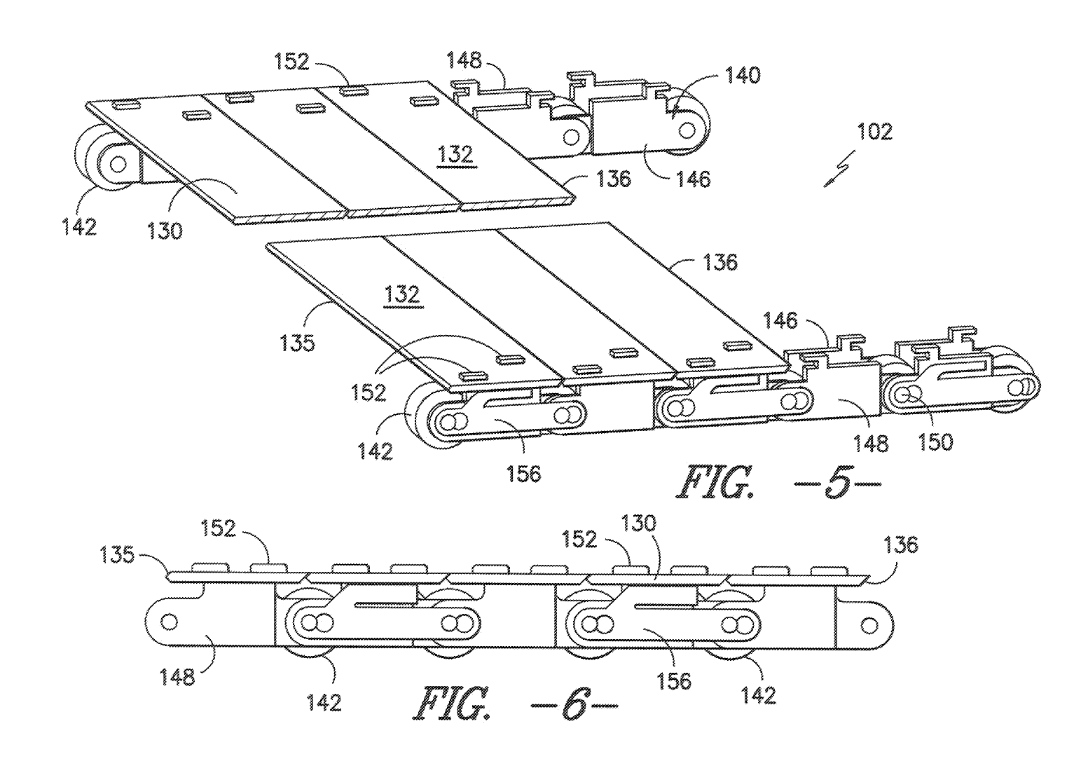

Conveyor 102 includes a plurality of interconnected slats 130. Each of the slats 130 has a respective flat planar outer surface 132 (FIG. 5) and transverse edges. Referring particularly to FIG. 6, it can be seen that each of the slats 130 has a leading transverse edge profile 135 and a trailing transverse edge profile 136. In the illustrated embodiment, the trailing edge profile 136 is inclined or slanted with respect to vertical. The leading transverse edge profile 135 has a camfered or double-angled profile, as is particularly seen in FIG. 6. The leading edge profile 135 cooperates with the trailing edge 136 of an adjacent slat 130 so as to define a tortuous non-vertical path through the adjacent slats 130 along the upper leg of the conveyor 102. This tortuous path inhibits sublimated source material from passing through the conveyor slats 130. Still referring to FIGS. 5 and 6, it can be seen that the adjacent slats 130 along the upper leg of the conveyor define a flat, planar surface whereby the outer surfaces 132 of the slats lie in a common horizontal plane and define an uninterrupted flat support surface for the substrates 14 conveyed through the assembly. This flat support surface prevents bowing of the glass substrates 14. In addition, the flat conveyor surface, in combination with the transverse edge profiles of the slats 130 discussed above, prevent back side coating of the substrates 14 with sublimated source material.

Referring again to the housing construction 104 depicted in FIGS. 3 and 4, it can be seen that the open deposition area 112 in the top wall 110 has a transverse dimension (relative to the conveyance direction of the substrates 14) that is less than the transverse length of the underlying slats 130. In essence, the open deposition area 112 defines a “picture frame” around a completely flat, planar surface of the conveyor 102 in its upper leg of travel. The flat surface defined by the upper surfaces 132 of the slats is “uninterrupted” in that at no location within the open deposition area 112 can a vertical line be drawn through the surface. As described above, even at the transverse edges 135,136 of adjacent slats 130, the transverse edge profiles define a non-vertical tortuous path that inhibits sublimated source material from passing therethrough.

Referring particularly to FIGS. 3 and 4, the housing 104 includes end walls 108 and side walls 106. The end walls 108, side walls 106, and top wall 110 are connected to each other by a tab and slot arrangement wherein tabs 114 on one wall engage within slots 116 on another wall. Pins 118 engage through the tabs 114 to retain the components in a connected assembly, as particularly illustrated in FIG. 4. This embodiment is particularly useful in that mechanical fasteners, such as screws, bolts, and the like, are not necessary to assemble the housing 104. The components of the housing 104 simply slide together and are pinned in position relative to each other. Assembly/disassembly of the housing 104 for maintenance or other procedures is a relatively easy process in this regard.

The housing 104, and conveyor 102 contained therein are configured for drop-in placement of the assembly 110 in the vapor deposition module 60. A plurality of braces 166 are attached to the side walls 106 and extend through slots in the top wall 110. These braces 166 define a plurality of lifting points for raising and lowering the assembly 100 into the casing 95 of the vapor deposition module 60. When maintenance is required, the entire conveyor assembly 100 is easily lifted from the module 60, and a spare assembly 100 is readily dropped in to replace the removed assembly 100. In this way, maintenance may be conducted on the removed assembly 100 while the processing line is returned to service. This keeps the vapor deposition line running in parallel with maintenance tasks. The conveyor assembly 100 sits on registration points within the casing 95 so that the different conveyor assemblies 100 are easily installed and removed.

Referring to FIG. 3, the top wall 110 defines an entry slot 120 and an exit slot 122 for the substrates 14 that are conveyed under the vapor deposition head 62. The clearance at these slots 120, 122 represents a potential source of leakage of the sublimated source material from the vapor deposition area. In this regard, it is desirable to keep the clearance between the upper surface of the substrates 14 at the entry and exit slots 120, 122 to a minimum. Plate members 124 may be configured with the top member 104 for this purpose. These plate members 124 may be adjustable relative to the top wall 110 and essentially define a seal with the substrates 14 being conveyed thereunder. It should be appreciated that any manner of sealing structure may be utilized in this regard.

The top wall member 110 may also cooperate with the vapor deposition head 62 to add additional sealing. For example, the seals 96 discussed above at the longitudinal ends of the vapor deposition head 62 may engage against sealing surfaces 126 defined by the top wall 110. This sealing arrangement ensures that the sublimated source material that passes through the distribution plate 88 is maintained in the open deposition area 112 of the top member 110 and does not escape at the interface of the conveyor assembly 100 and vapor deposition head 62.

Referring again to FIGS. 2 and 3, the conveyor assembly 100 may include any manner of additional functional components within the housing 104. For example, any number or configuration of heater elements 158 may be configured within the housing 104, or between the housing 104 and the casing 95. Any configuration of thermal shields 160 may also be contained within the housing 104. Referring to FIG. 4, the shields 160 may include tabs 162 that extend through the side walls 106. Pins 164 may engage through the tabs to secure the shields 160 in place relative to the housing 104.

Tracks 144 are disposed along the upper leg of the conveyor 102 and provide a running surface for the conveyor rollers, as discussed in greater detail below. The tracks 144 may include tabs 145 that also extend through the side wall 106 and are engaged by pins 147.

The conveyor 102 may run in its endless loop path around sprockets 138 that are rotatably supported by the housing side walls 106. The sprockets 138 include teeth or cogs that engage with the conveyor rollers 142. At least one of the sprockets 138 is a driven sprocket, while the opposite sprocket is an idler sprocket. Typically, the upstream sprocket 138 serves as the idler sprocket.

In a particular embodiment, the conveyor slats 130 are interconnected by link assemblies 140. These link assemblies 140 may take on various configurations. A particularly unique configuration in accordance with aspects of the invention is illustrated in FIGS. 5 and 6. In this embodiment, the link assemblies 140 include inner and outer link plates 146, 148. Rollers 142 are contained between the plates 146, 148 by respective axles 150. The axles 150 serve to interconnect adjacent inner and outer plates 146, 148 at the respective longitudinal ends thereof, and to also rotationally support the rollers 142 between the plates. Each of the inner and outer plates 146, 148 includes a tab 152 that extends through a slot in the slats 130. These tabs 152 have an undercut (seen in FIG. 5) such that after insertion of the tabs 152 through the slots, the plates 146, 148 are shifted relative to the tabs slats 130 to ensure that the slats 130 cannot be pulled from the plates 146, 148.

Referring to FIG. 5, one end of the axles 150 has an enlarged head that prevents the axles from being pulled through the plates 146, 148. The opposite end of the axles 150 protrudes through the outer plates 148. A clip 156 attaches to the end of the axles 150, and extends between two axles. Thus, the clip 156 has a longitudinal length that is essentially the same as one of the plates 146, 148, and does not inhibit travel of the link assemblies 140 around the sprockets 138.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A conveyor assembly for use in a vapor deposition apparatus wherein a sublimated source material is deposited as a thin film on a photovoltaic (PV) module substrate, said assembly comprising:
a housing defining an enclosed interior volume;
a conveyor operably disposed within said housing to be driven in an endless loop path within said housing, said endless loop path having an upper leg that moves in a conveyance direction, and a lower leg that moves in an opposite return direction;
said housing further comprising a top member defining an open deposition area in said upper leg of said endless loop path; and,
said conveyor comprising a plurality of interconnected slats, each of said slats having a respective flat planar outer surface and transverse edge profiles such that, in said upper leg of said endless loop path, said outer surfaces of said slats lie in a common horizontal plane and define an uninterrupted flat support surface for a substrate conveyed through said assembly.

2. The conveyor assembly as in claim 1, wherein said open deposition area has a transverse dimension that is less than a transverse length of said slats.

3. The conveyor assembly as in claim 1, wherein said conveyor runs around opposite sprockets in said housing, at least one of said sprockets being a driven sprocket.

4. The conveyor assembly as in claim 1, wherein said transverse edge profiles of said slats define a tortuous non-vertical path to sublimated source material along said upper leg of said endless loop path.

5. The conveyor assembly as in claim 4, wherein said transverse edge profiles comprise chamfered surfaces.

6. The conveyor assembly as in claim 1, wherein said slats are interconnected by link assemblies at opposite longitudinal ends of said slats, said link assemblies having rollers configured therewith, said rollers running along tracks disposed within said housing at least along said upper leg of said endless loop path.

7. The conveyor assembly as in claim 6, wherein said link assemblies comprise inner and outer link plates, said rollers supported by an axle between said inner and outer link plates, said axles further interconnecting inner and outer link plates of adjacent said slats.

8. The conveyor assembly as in claim 7, wherein said link plates further comprise tabs that engage through slots in said slats to secure said slats to said link assemblies.

9. The conveyor assembly as in claim 8, wherein said link assemblies further comprise clips that attach to adjacent said axles.

10. The conveyor assembly as in claim 6, wherein said conveyor runs around opposite sprockets in said housing, at least one of said sprockets being a driven sprocket, said rollers engaged by drive cogs on said sprockets.

11. The conveyor assembly as in claim 1, wherein said housing defines and entry slot and an exit slot for a substrate conveyed through said assembly, said slots defined by plate members attached to said top member of said housing.

12. The conveyor assembly as in claim 1, wherein said top member of said housing defines a sealing surface for engagement by a vapor deposition head around said deposition area.

13. The conveyor assembly as in claim 12, wherein said housing is configured for drop-in placement of said assembly in a vapor deposition module, with the vapor deposition head configured on said assembly within the vapor deposition module.

14. The conveyor assembly as in claim 1, wherein said housing comprises a plurality of wall members in a slotted, slip-fit engagement wherein tabs on one said wall engage in slots in an adjacent said wall, and further comprising removable pins extending through said tabs to secure said slip-fit engagement.

15. The conveyor assembly as in claim 1, further comprising a heater disposed within said enclosed volume of said housing to reduce plating of the sublimated source material on said conveyor and said housing.

16. A vapor deposition module for deposition of a sublimated source material as a thin film on a photovoltaic (PV) module substrate conveyed through said vapor deposition module, comprising:
a casing;
a vapor deposition head operably configured within said casing to sublimate a source material;
a conveyor assembly operably configured within said casing below said vapor deposition head, said conveyor assembly further comprising
a housing defining an enclosed interior volume;
a conveyor operably disposed within said housing to be driven in an endless loop path within said housing, said endless loop path having an upper leg that moves in a conveyance direction, and a lower leg that moves in an opposite return direction;
said housing further comprising a top member defining an open deposition area wherein said conveyor is exposed to said vapor deposition head as said conveyor moves in said upper leg of said endless loop path;
said conveyor comprising a plurality of interconnected slats, each of said slats having a respective flat planar outer surface and transverse edge profiles such that, in said upper leg of said endless loop path, said outer surfaces of said slats lie in a common horizontal plane and define an uninterrupted flat support surface for a substrate conveyed through said module; and,
wherein said vapor deposition head is configured on said conveyor assembly housing such that sublimated source material from said vapor deposition head is directed to said open deposition area and onto an upper surface of a substrate supported by said conveyor.

17. The vapor deposition module as in claim 16, wherein said conveyor assembly housing is configured for drop-in placement in said casing, with said vapor deposition head configured on said conveyor assembly within said vapor deposition module.

18. The vapor deposition module as in claim 16, wherein said slats are interconnected by link assemblies at opposite longitudinal ends of said slats, said link assemblies supporting rollers, said rollers running along tracks disposed within said conveyor assembly housing at least along said upper leg of said endless loop path.

19. The vapor deposition module as in claim 18, wherein said link assemblies comprise inner and outer link plates, said rollers supported by an axle between said inner and outer link plates, said axles further interconnecting adjacent inner and outer link plates, said link plates further comprising tabs that engage through slots in said slats to secure said slats to said link assemblies, and clips that attach to adjacent said axles.

20. The vapor deposition module as in claim 19, wherein said conveyor runs around opposite sprockets in said conveyor assembly housing, at least one of said sprockets being a driven sprocket, said rollers engaged by drive cogs on said sprockets.
